(19) United States
(12) Patent Application Publication
(10) Pub. No.: US 2009/0027315 A1
(43) Pub. Date: Jan. 29, 2009

(54) Organic light emitting display and driving method thereof

(76) Inventors: Do-Ik Kim, Suwon-si (KR); Jae-Woo Ryu, Suwon-si (KR); Wang-Jo Lee, Suwon-si (KR); Hyung-Soo Kim, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 12/220,561

(22) Filed: Jul. 25, 2008

(30) Foreign Application Priority Data
Jul. 27, 2007 (KR) 10-2007-0075558

(51) Int. Cl. G09G 3/30

(52) U.S. Cl. 345/76; 315/169.3

(57) ABSTRACT

An organic light emitting display is disclosed. The display comprises: a scan driver for sequentially supplying a scan signal to scan lines during scan periods of a plurality of sub-frames included in a frame; a data driver for supplying a data signal to data lines when the scan signal is supplied; pixels disposed at a display region of a panel to be coupled to the scan lines and the data lines, and receiving a first power source voltage and a second power source voltage; at least one dummy organic light emitting diode disposed at a non-display region of the panel; and a power source block for supplying an electric current to the dummy organic light emitting diode and for generating the first power source voltage based on a voltage of the dummy organic light emitting diode corresponding to the electric current.

### CROSS-REFERENCE TO RELATED APPLICATION

This application claims priority to and the benefit of Korean Patent Application No. 10-2007-0075558, filed on Jul. 27, 2007, in the Korean Intellectual Property Office, the entire content of which is incorporated herein by reference.

### BACKGROUND

1. Field

The field relates to an organic light emitting display and a driving method thereof, and more particular to an organic light emitting display and a driving method thereof, in which display images of uniform luminance regardless of a temperature and a resistance change of an organic light emitting diode.

2. Description of the Related Technology

Recently, various flat plate displays of reduced weight and volume that are disadvantages of cathode ray tubes (CRT) have been developed. Flat panel displays include liquid crystal displays (LCD), field emission displays (FED), plasma display panels (PDP), and organic light emitting displays.

Among the flat panel displays, the organic light emitting displays make use of organic light emitting diodes that emit light by re-combination of electrons and holes. The organic light emitting display has advantages of high response speed and small power consumption.

FIG. 1 is a schematic view showing a pixel of a general organic light emitting display.

With reference to FIG. 1, the pixel 4 of a conventional organic light emitting display includes an organic light emitting diode OLED and a pixel circuit 2. The pixel circuit 2 is coupled to a data line Dm and a scan line Sn, and controls the organic light emitting diode OLED.

An anode electrode of the organic light emitting diode OLED is coupled to a pixel circuit 2, and a cathode electrode thereof is coupled to a second power source ELVSS. The organic light emitting diode OLED generates light of a predetermined luminance corresponding to an electric current from the pixel circuit 2.

When a scan signal is supplied to the scan line Sn, the pixel circuit 2 controls an amount of electric current provided to the organic light emitting diode OLED corresponding to a data signal provided to the data line Dm. So as to do this, the pixel circuit 2 includes a second transistor M2, a first transistor M1, and a storage capacitor Cst. The second transistor M2 is coupled between a first power source ELVDD and the organic light emitting diode OLED. The first transistor M1 is coupled between the data line Dm and the scan line Sn. The storage capacitor Cst is coupled between a gate electrode and a first electrode of the second transistor M2.

A gate electrode of the first transistor M1 is coupled to the scan line Sn, and a first electrode thereof is coupled to the data line Dm. A second electrode of the first transistor M1 is coupled with one terminal of the storage capacitor Cst. Here, the first electrode is a source electrode or a drain electrode, and the second electrode is an electrode different from the first electrode. For example, when the first electrode is the source electrode, the second electrode is the drain electrode. When a scan signal is supplied to the first transistor M1 coupled with the scan line Sn and the data line Dm, it is turned-on to provide a data signal from the data line Dm to the storage capacitor Cst. At this time, the storage capacitor Cst is charged with a voltage corresponding to the data signal.

A gate electrode of the second transistor M2 is coupled to one terminal of the storage capacitor Cst, and a first electrode thereof is coupled to another terminal of the storage capacitor Cst and a first power source ELVDD. Further, a second electrode of the second transistor M2 is coupled with an anode electrode of the organic light emitting diode OLED. The second transistor M2 controls an amount of electric current flowing from the first power source ELVDD to a second power source ELVSS through the organic light emitting diode OLED according to the voltage charged in the storage capacitor Cst. At this time, the organic light emitting diode OLED emits light corresponding to an amount of an electric current supplied from the second transistor M2.

In practice, the pixel 4 of the conventional organic light emitting display displays images of desired luminance by repeating the aforementioned procedure. On the other hand, during a digital drive in which the second transistor M2 functions as a switch, a voltage of the first power source ELVDD and a voltage of the second power source ELVSS are supplied to the organic light emitting diode OLED. Accordingly, the organic light emitting diode OLED emits light with a voltage regulation drive. In the digital drive method, an electric current is sensitively changed based on a temperature and a resistance increase according to a degradation of the organic light emitting diode OLED. This causes a problem, because of which the display can not display images of desired luminance.

In detail, a current amount flowing from the pixel circuit 2 to the organic light emitting diode OLED changes according to a variation of a temperature. In this case, there arises a problem that luminance of displayed image is changed corresponding to the variation of the temperature. Further, as time goes by, the organic light emitting diode OLED is degraded. When the organic light emitting diode OLED is degraded, resistance of the organic light emitting diode OLED is increased. Accordingly, an electric current flowing to the organic light emitting diode OLED is reduced. This causes the luminance of images to be reduced.

### SUMMARY OF CERTAIN INVENTIVE ASPECTS

One aspect is an organic light emitting display including a scan driver configured to sequentially supply a scan signal to scan lines during a scan period of a plurality of sub-frames in a frame, a data driver configured to supply a data signal to data lines substantially when the scan signal is supplied, a plurality of pixels disposed in a display region of a panel, the pixels coupled to the scan lines and the data lines, and configured to receive a first power voltage and a second power voltage in order to be driven, at least one dummy organic light emitting diode disposed at a non-display region of the panel, and a power source block configured to supply an electric current to the dummy organic light emitting diode and to generate the first power voltage based on a voltage of the dummy organic light emitting diode corresponding to the electric current.

Another aspect is a method of driving an organic light emitting display, the display including pixels configured to provide an electric current from a first power source to a second power source according to a data signal, the method including supplying an electric current to at least one dummy organic light emitting diode using a current source, where a voltage of the dummy organic light emitting diode is generated as a result of the supplied current, and generating the voltage of the first power source according to the voltage of the at least one dummy organic light emitting diode.

Another aspect is an organic light emitting display including a plurality of pixels configured to receive a first power voltage, at least one dummy organic light emitting diode, and a power source block configured to supply an electric current to the dummy organic light emitting diode and to generate the first power voltage based on a voltage of the dummy organic light emitting diode corresponding to the electric current.

### BRIEF DESCRIPTION OF THE DRAWINGS

These and/or other aspects and features of the invention will become apparent and more readily appreciated from the following description of the certain embodiments, taken in conjunction with the accompanying drawings of which:

FIG. 1 is a schematic view showing a pixel of a conventional organic light emitting display;

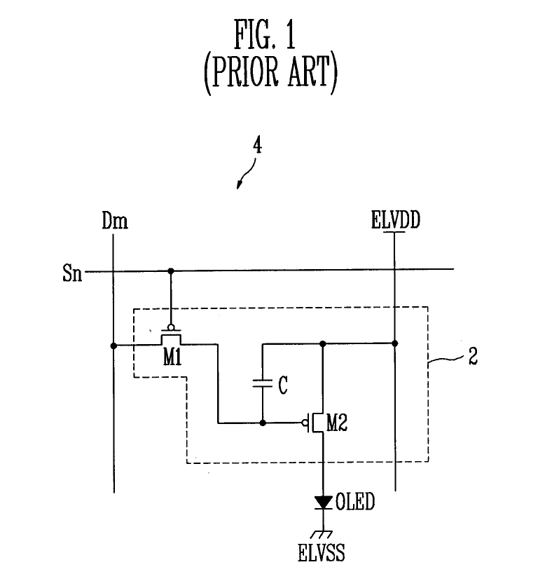

FIG. 2 is a schematic view showing an organic light emitting display according to an embodiment;

FIG. 3 is a timing view showing one frame of the organic light emitting display according to an embodiment;

FIG. 4 is a schematic view showing an organic light emitting display according to another embodiment; and

FIG. 5 is a timing view showing an example of a control signal supplied to a switching element shown in FIG. 4.

### DETAILED DESCRIPTION OF CERTAIN INVENTIVE EMBODIMENTS

Hereinafter, certain embodiments will be described with reference to the accompanying drawings. Here, when a first element is described as being coupled to a second element, the first element may be not only directly coupled to the second element but may also be indirectly coupled to the second element via a third element. Further, elements that are not essential to the complete understanding of the invention are omitted for clarity. Also, like reference numerals refer to like elements throughout.

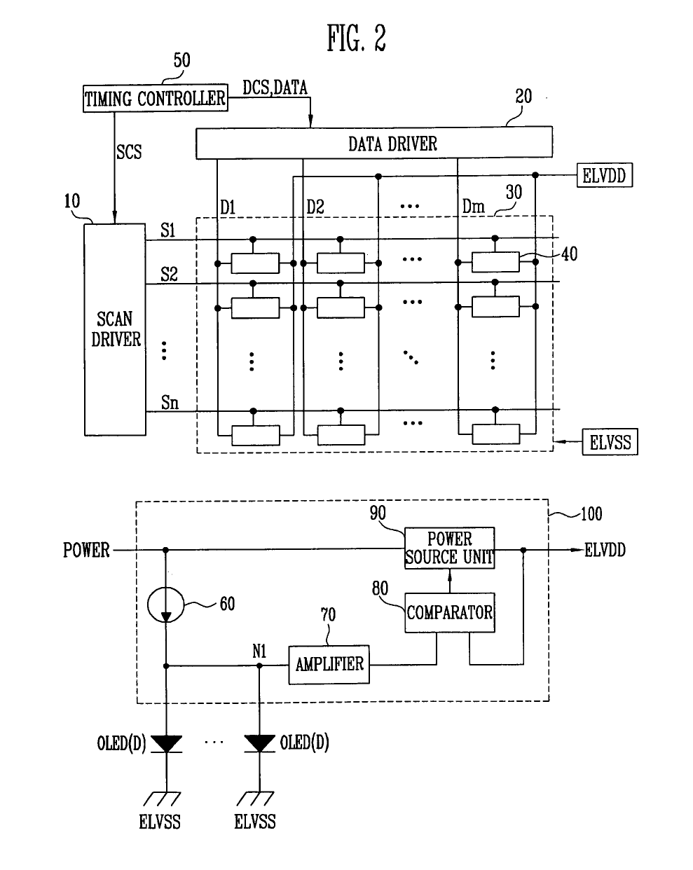

Hereinafter, embodiments will be described with reference to FIG. 2 to FIG. 5.

FIG. 2 is a view showing an organic light emitting display according to some embodiments.

With reference to FIG. 2, the organic light emitting display includes a pixel portion 30 having pixels 40, a scan driver 10, a data driver 20, a timing control unit 50, and a power source block 60. The pixels 40 are coupled to scan lines S1 through Sn and data lines D1 through Dm. The scan driver 10 drives the scan lines S1 through Sn. The data driver 20 drives the data lines D1 through Dm. The timing control unit 50 controls the scan driver 10 and the data driver 20. The power source block 100 generates a first power source ELVDD while supplying an electric current to a dummy organic light emitting diode OLED(D). In some embodiments, the dummy organic light emitting diode OLED(D) is disposed at a region other than a valid display part of a panel.

The timing controller 50 generates a data driving signal DCS and a scan driving signal SCS corresponding to received synchronizing signals (not shown). The data driving signal DCS generated from the timing controller 50 is provided to the data driver 20, and the scan driving signal SCS is provided to the scan driver 10. Further, the timing controller 50 provides a data signal DATA to the data driver 20.

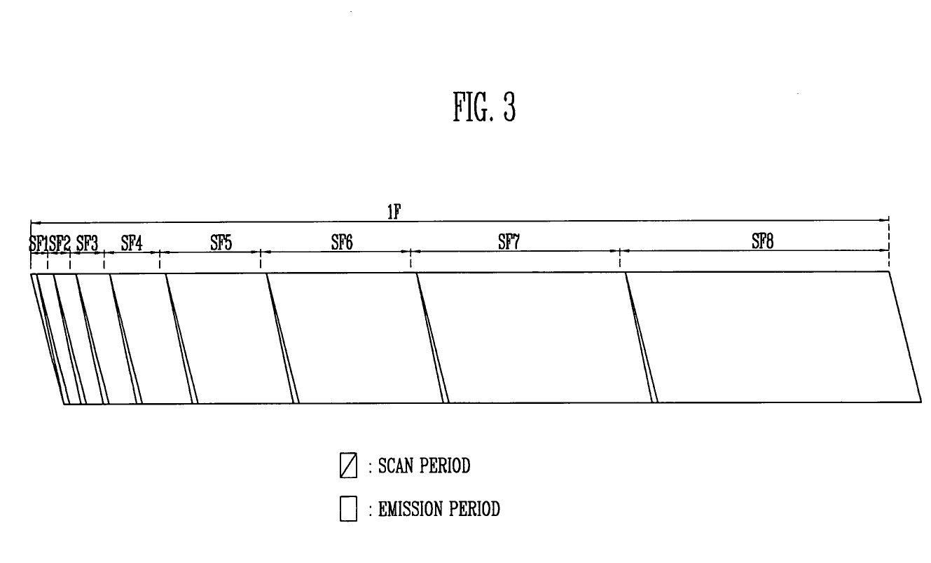

The scan driver 10 sequentially supplies a scan signal to the scan lines S1 through Sn. Here, as shown in FIG. 3, the scan driver 10 sequentially supplies a scan signal to scan lines S1 to Sn during every scan period of each of the sub-frames in one frame 1F. When the scan signal is sequentially supplied to the scan lines S1 through Sn, the pixels 40 are sequentially selected, and the selected pixels 40 receive a data signal from the data lines D1 to Dm.

The data driver 20 supplies a data signal to data lines D1 to Dm each time the scan signal is supplied during a scan period of a sub-frame. Accordingly, the data signal is supplied to the pixels 40 selected by the scan signal. Meanwhile, the data driver 20 supplies a first data signal and a second data signal as the data signal. Here, the first data signal and the second data signal cause the pixels 40 to be emitted and not to be emitted, respectively. Accordingly, when the pixels have received the first data signal during an emission period in a sub-frame, they display images while emitting light during the emission period.

The pixel portion 30 receives a voltage of the first power source ELVDD and a voltage of the second power source ELVSS and provides them to the pixels 40. After the pixels 40 receive the power of the first power source ELVDD and the power of the second power source ELVSS, when the scan signal is supplied, they receive a data signal, and emit or non-emit light according to the data signal. Here, a voltage of the first power source ELVDD is greater than that of the second power source ELVSS. The pixel portion 30 is disposed at a valid display region of a panel.

Besides organic light emitting diodes included in each of pixels 40, the organic light emitting display includes at least one organic light emitting diode OLED(D), which is formed at a non-display region of a panel.

The power source block 100 generates a first power source ELVDD to source a desired current to the pixels 40 regardless of a temperature and a resistance change, and supplies the first power source ELVDD to the pixels 40. To do this, the power source block 100 includes a current source 60, an amplifier 70, a comparator 80, and a power source unit 90. In some embodiments, the amplifier 70 is omitted.

The current source 60 supplies an electric current to the dummy organic light emitting diode OLED(D) as a constant current source. Here, the at least one dummy organic light emitting diode OLED(D) is coupled between the current source 60 and the second power source ELVSS. When a current is supplied from the current source 60, a voltage corresponding to the current and to the electrical parameters of the dummy organic light emitting diode(s) OLED(D) is at the first node N1.

The amplifier 70 is a peak to peak hold amplifier, which supplies the voltage at the first node N1 to the comparator 80.

The comparator 80 compares the voltage supplied from the amplifier 70 with a voltage of a first power source ELVDD generated by the power source unit 90, and supplies a compassion result to the power source unit 90.

The power source unit 90 adjusts a voltage of the first power source ELVDD to become substantially identical to the voltage supplied from the amplifier 70 according to the comparison result of the comparator 80, and supplies the adjusted voltage of the first power source ELVDD to the pixels 40.

The following is a description of the organic light emitting display according to one embodiment. First, the current source 60 supplies a constant current to the dummy organic light emitting diode OLED(D), regardless of a temperature and a resistance change of the dummy organic light emitting diode OLED(D). When an electric current of the current source 60 is supplied to the dummy organic light emitting diode OLED(D), a voltage is at the first node N1. The voltage at the first node N1 is a voltage causing the electric current of the current source 60 to be flown regardless of the temperature and the resistance change of the dummy organic light emitting diode OLED(D).

Meanwhile, each of the pixels 40 controls a supply time of a current flowing from the first source ELVDD to the second power source ELVSS through the organic light emitting diode corresponding to the data signal. Accordingly, each of the pixels 40 should maintain the electric current through the pixels 40 constant regardless of the temperature and the resistance change of the organic light emitting diode.

To do this, the electric current of the current source in the power source block 100 remains constant. The voltage from the power source block 100 changes to keep the current through the dummy organic light emitting diode(s) OLED(D) constant. Accordingly, the voltage supplied to the pixels 40 causes a constant current to be flown in the pixels 40. For example, the electric current of the current source 60 may be determined to flow a desired electric current through each of the pixels 40 corresponding to a size of a panel. For example, the electric current of the current source 60 may be set as the same current as a constant current flowing through each of the pixels 40.

The voltage applied to the first node N1 is supplied to the amplifier 70. The amplifier 70 supplies the voltage applied from the first node N1 to the comparator 80. The comparator 80 compares the voltage from the amplifier 70 with the first source generated by the power source unit 90, and supplies the comparison result to the power source unit 90. Accordingly, the power source unit 90 adjusts a voltage value of the first source ELVDD to become substantially identical with the voltage from the amplifier 70, and supplies the adjusted voltage value of the first power source ELVDD to the pixels 40.

Next, the pixels 40 display an image by supplying an electric current from the first source ELVDD to the second power source ELVSS through the organic light emitting diode.

Here, since the first power source is generated to source a constant current by the current source 60, a desired current may be sourced through each of the pixels 40, with the result that the pixels may display image of uniform luminance regardless of external environment.

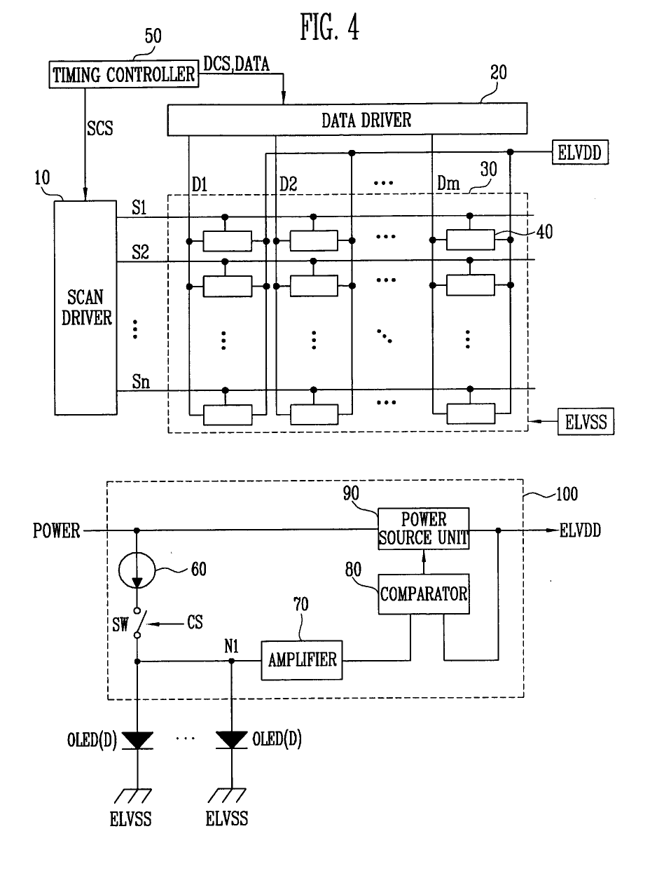

FIG. 4 is a schematic view showing an organic light emitting display according to other embodiments. Parts of FIG. 4 corresponding to those of FIG. 2 are generally designated by the same symbols.

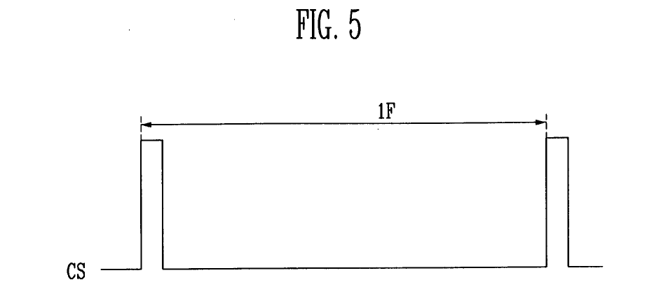

With reference to FIG. 4, the organic light emitting display includes a switching element SW, which is disposed between the current source 60 and the first node N1. The switching element SW1 is turned-on every time period to supply an electric current to the first node N1. FIG. 5 is a timing view showing an example of a control signal supplied to the switching element SW shown in FIG. 4. For example, as shown in FIG. 5, the switching element SW may be set to be turned-on during a part of one frame period corresponding to a control signal CS. When the switching element SW is turned-on, a predetermined voltage corresponding to the electric current of the current source 60 is applied to the first node N1.

The amplifier 70 supplies the voltage applied to the first node N1 to the comparator 80. Further, when the switching element SW is turned-off, the amplifier 70 maintains and supplies the voltage at the first node N1 to the comparator 80 during a turning-on time period of the switching element SW. In some embodiments, the comparator or the power source unit are configured to maintain their output voltage despite the voltage at the first node N1 changing because of the switching element SW being turned off.

In the organic light emitting display, since the switching element SW supplies an electric current to the dummy organic light emitting diode OLED(D) only during a part of one frame period, an emission time of the dummy organic light emitting diode OLED(D) can be minimized.

In an organic light emitting display and a method for driving the same, a constant current is supplied to the dummy organic light emitting diode disposed at a non-display region of a panel, and a first voltage is generated using an applied voltage corresponding to the constant current. Accordingly, images of uniform luminance can be display regardless of a temperature and the degradation of an organic light emitting diode. In addition, since an electric current is supplied during a part of one frame period, the occurrence of unnecessary light can be minimized.

Although embodiments of the present invention have been shown and described, it would be appreciated by those skilled in the art that changes might be made in these embodiments without departing from the principles and spirit of the invention.

What is claimed is:

1. An organic light emitting display comprising:
a scan driver configured to sequentially supply a scan signal to scan lines during a scan period of a plurality of sub-frames in a frame;
a data driver configured to supply a data signal to data lines substantially when the scan signal is supplied;
a plurality of pixels disposed in a display region of a panel, the pixels coupled to the scan lines and the data lines, and configured to receive a first power voltage and a second power voltage in order to be driven;
at least one dummy organic light emitting diode disposed at a non-display region of the panel; and
a power source block configured to supply an electric current to the dummy organic light emitting diode and to generate the first power voltage based on a voltage of the dummy organic light emitting diode corresponding to the electric current.

2. The organic light emitting display as claimed in claim 1, wherein the power source block includes:
a power source unit configured to generate the first power voltage;
a current source configured to supply the electric current to the dummy organic light emitting diode;
an amplifier configured to transfer the voltage of the dummy organic light emitting diode to a comparator when the electric current is supplied; and
a comparator configured to compare the voltage from the amplifier with the first power voltage and to supply the comparison result to the power source unit,
wherein the power source unit is configured to adjust a voltage the first power voltage to be substantially identical to the voltage from the amplifier.

3. The organic light emitting display as claimed in claim 2, wherein the at least one dummy organic light emitting diode is coupled between the current source and the second power source.

4. The method as claimed in claim 3, wherein the at least one dummy organic light emitting diode comprises a plurality of dummy organic light emitting diodes coupled in parallel.

5. The organic light emitting display as claimed in claim 2, wherein the current value of the current source is substantially equal to the current to flow in each of the diodes of the pixels.

6. The organic light emitting display as claimed in claim 2, further comprising a switching element disposed between the current source and the dummy organic light emitting diode.

7. The organic light emitting display as claimed in claim 6, wherein the switching element is turned-on during only a part of a frame period.

8. The organic light emitting display as claimed in claim 7, wherein the amplifier is configured to continuously supply the voltage of the dummy organic light emitting diode when the switching element is turned-on to the comparator during the frame period.

9. The organic light emitting display as claimed in claim 8, wherein the amplifier is a peak to peak hold amplifier.

10. The organic light emitting display as claimed in claim 1, wherein the data driver supplies one of a first data signal and a second data signal to the data lines during a supply time period of the scan signal, wherein the first data signal causes the pixels to emit light and the second data signal cause the pixels not to emit light.

11. A method of driving an organic light emitting display, the display including pixels configured to provide an electric current from a first power source to a second power source according to a data signal, the method comprising:
supplying an electric current to at least one dummy organic light emitting diode using a current source, wherein a voltage of the dummy organic light emitting diode is generated as a result of the supplied current; and
generating the voltage of the first power source according to the voltage of the at least one dummy organic light emitting diode.

12. The method as claimed in claim 11, wherein the voltage of the first power source is substantially identical to the voltage of the at least one dummy organic light emitting diode.

13. The method as claimed in claim 11, wherein an electric current of the current source is supplied to the at least one dummy organic light emitting diode during only a part of each frame period.

14. The method as claimed in claim 11, wherein the at least one dummy organic light emitting diode is coupled between the current source and the second power source.

15. The method as claimed in claim 14, wherein the at least one dummy organic light emitting diode comprises a plurality of dummy organic light emitting diodes connected in parallel.

16. The method as claimed in claim 11, wherein the at least one dummy organic light emitting diode is disposed in an non-display region of the display.

17. An organic light emitting display comprising:
a plurality of pixels configured to receive a first power voltage;
at least one dummy organic light emitting diode; and
a power source block configured to supply an electric current to the dummy organic light emitting diode and to generate the first power voltage based on a voltage of the dummy organic light emitting diode corresponding to the electric current.

18. The organic light emitting display as claimed in claim 17, wherein the power source block is configured to generate the first power voltage based on the output of a comparator, wherein the comparator has a first input based on the voltage of the dummy organic light emitting diode and a second input based on the first power voltage.

19. The organic light emitting display as claimed in claim 17, wherein the dummy organic light emitting diode comprises a plurality of organic light emitting diodes connected in parallel.

20. The organic light emitting display as claimed in claim 17, wherein the power source block comprises a switching element and wherein the power source block is configured to selectively supply the electric current to the dummy organic light emitting diode according to the state of the switching element.
